(19) United States
(12) Patent Application Publication
(10) Pub. No.: US 2015/0362531 A1
(43) Pub. Date: Dec. 17, 2015

(54) Edison Base Fuse Meter for Power Metering

(71) Applicant: Jeffrey Randall Sweet, Jones Creek, TX (US)

(72) Inventor: Jeffrey Randall Sweet, Jones Creek, TX (US)

(21) Appl. No.: 14/738,704

(22) Filed: Jun. 12, 2015

Related U.S. Application Data
(60) Provisional application No. 62/013,450, filed on Jun. 17, 2014.

(51) Int. Cl. G01R 15/18; G01R 19/00; G01R 21/00

(52) U.S. Cl. CPC G01R 15/18; G01R 21/00; G01R 19/0092

(57) ABSTRACT

An Edison base fuse meter includes a female Edison base connector, a male Edison base connecter, a socket extender, and two current transformer wires. The socket extender is physically connected in between the female Edison base connector and the male Edison base connector. The socket extender includes at least two wires that electrically connect the terminals of the female Edison base connector and the male Edison base connector. The socket extender includes a current transformer that surrounds one or more wires of the at least two wires so that a transformer current is induced in the current transformer in response to a current in the one or more wires. The two current transformer wires are electrically connected to each end of the current transformer. The two current transformer wires are used for externally measuring the transformer current induced in the current transformer.

### CROSS-REFERENCE TO RELATED APPLICATION

This application claims the benefit of U.S. Provisional Patent Application No. 62/013,450, filed Jun. 17, 2014, the content of which is incorporated by reference herein in its entirety.

### INTRODUCTION

Power plug meters are commonly used today to measure the power consumption of a home appliance, computer, television, lamp, or any other type of electrical device used in a home or office. By using these meters, a home owner or property owner can determine the electrical devices consuming the most power. By limiting the usage of the devices found to consume the most power, a homeowner or property owner can reduce their electrical bill and save money.

A power plug meter typically consists of a male outlet plug connected to an electrical current meter or ammeter connected, in turn, to a female outlet plug. In other words, the typical power plug meter is an outlet extender designed to plug into a common 110V or 220 V electrical power outlet, and, at the same time, receive a plug of a power cord from any electrical device. A typical power plug meter can also include a display for displaying the power consumption or can include a communications device for communicating this information to another device for display or storage. The communications device can be as simple as a wired transceiver or as complex as a wireless transceiver.

In addition to monitoring power outlets, some power plug meters, such as the Brultech ECM-1220, include additional attachments such as a current transformer (CT) clamping loop to measure the power consumption directly from power cords of electrical devices or wires from electrical panels. Measuring the power consumption of individual breaker or fuses of electrical panels can be particularly helpful for home owners or property owners. For example, an apartment owner may have a single electrical panel for multiple apartments. If the apartment owner would like to monitor the power consumption of each apartment, the logical location for this monitoring is at one or more breakers or fuses for each apartment.

Although power plug meters, such as the Brultech ECM-1220, can provide a temporary means for monitoring electrical panels such as a clamping loop, there are currently no permanent means for monitoring the individual circuits of electrical panels. In particular, many older properties have electrical panels that include Edison base fuses (also called Edison screw fuses or Edison fuses). As a result, there is a need to permanently monitor the power consumption of the individual circuits of an Edison base fuse box.

### BRIEF DESCRIPTION OF THE DRAWINGS

FIG. 1 is an exemplary side view of an Edison base fuse meter, in accordance with various embodiments.

FIG. 2 is an exemplary alternate side view of an Edison base fuse meter, in accordance with various embodiments.

FIG. 3 is an exemplary schematic diagram of the electrical connections of an Edison base fuse meter, in accordance with various embodiments.

FIG. 4 is an exemplary side view of an Edison base fuse meter with a socket extender that has an oblique angle, in accordance with various embodiments.

FIG. 5 is an exemplary alternate side view of an Edison base fuse meter with a socket extender that has an oblique angle, in accordance with various embodiments.

FIG. 6 is an exemplary side view of an Edison base fuse meter with a flexible socket extender, in accordance with various embodiments.

FIG. 7 is an exemplary alternate side view of an Edison base fuse meter with a flexible socket extender, in accordance with various embodiments.

FIG. 8 is an exemplary side view of a cartridge fuse meter surrounding a 60 amp cartridge fuse, in accordance with various embodiments.

FIG. 9 is an exemplary side view of a cartridge fuse meter surrounding a 100 amp cartridge fuse, in accordance with various embodiments.

FIG. 10 is an exemplary view of a circuit breaker meter surrounding a wire of a circuit breaker, in accordance with various embodiments.

Before one or more embodiments of the invention are described in detail, one skilled in the art will appreciate that the invention is not limited in its application to the details of construction, the arrangements of components, and the arrangement of steps set forth in the following detailed description. The invention is capable of other embodiments and of being practiced or being carried out in various ways. Also, it is to be understood that the phraseology and terminology used herein is for the purpose of description and should not be regarded as limiting.

### DETAILED DESCRIPTION

### Fuse Meters

As described above, there is a need to permanently monitor the power consumption of the individual circuits of an Edison base fuse box or panel. In addition, it is desirable that this monitoring take place without significantly modifying the Edison base fuse box.

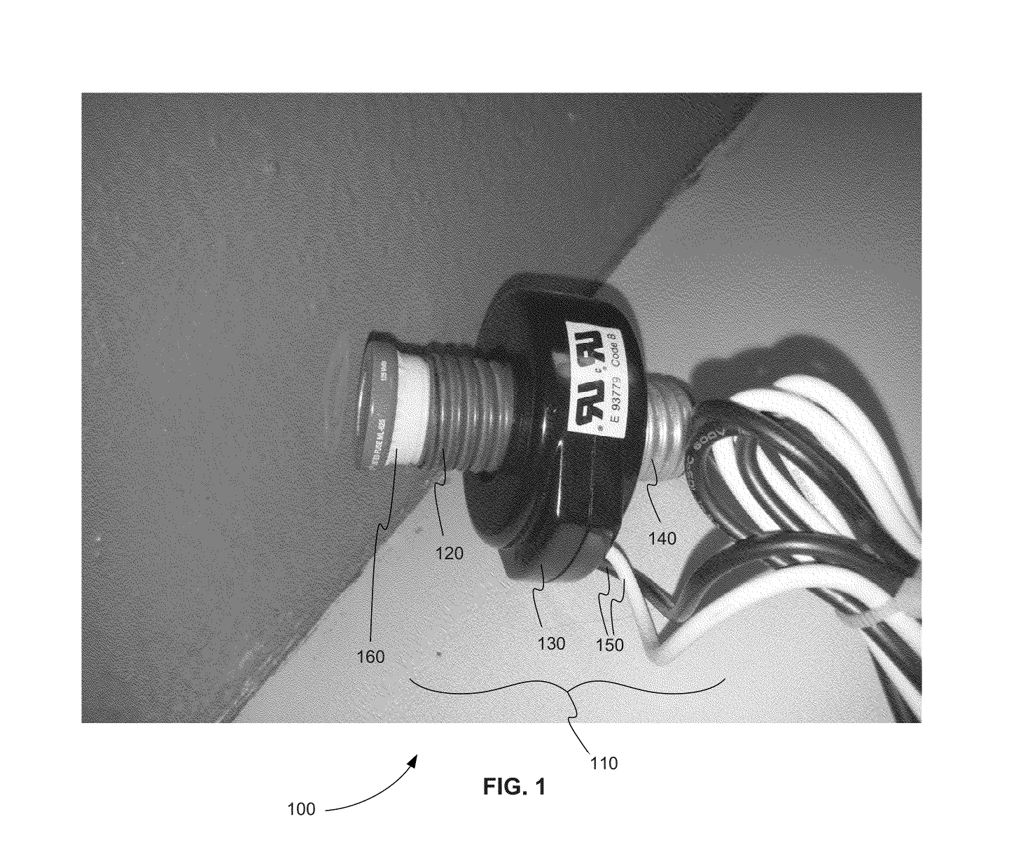

FIG. 1 is an exemplary side view 100 of an Edison base fuse meter, in accordance with various embodiments. Edison base fuse meter 110 includes female Edison base connector 120 connected to socket extender 130, in turn, connected to male Edison base connector 140. In addition, wires 150 extend from socket extender 130. Socket extender 130 includes one or more cables (not shown) and a current measurement device (not shown). The one or more cables of socket extender 130 are used to electrically connect female Edison base connecter 120 and male Edison base connector 140. The current measurement device of socket extender 130 is used to measure the current in the one or more cables of socket extender 130. The current measurement device measures the alternating current (AC) in the one or more cables, for example.

Female Edison base connector 120 is designed to receive Edison base fuse 160. In others words, Edison base fuse 160 is threaded into female Edison base connector 120. Male Edison base connector 140 is designed to be threaded into a female Edison base connector of an Edison base fuse box (not shown).

Essentially, Edison base fuse meter 110 acts as a socket extender for an Edison base fuse box. Edison base fuse meter 110 provides a permanent solution for monitoring an electrical circuit, while requiring little or no modification to the Edison base fuse box. Depending on the length of Edison base fuse meter 110 the door of the Edison base fuse box may have to be modified. In various embodiments, for example, the door of the Edison base fuse box is extended to increase the workable space for Edison base fuse meter 110.

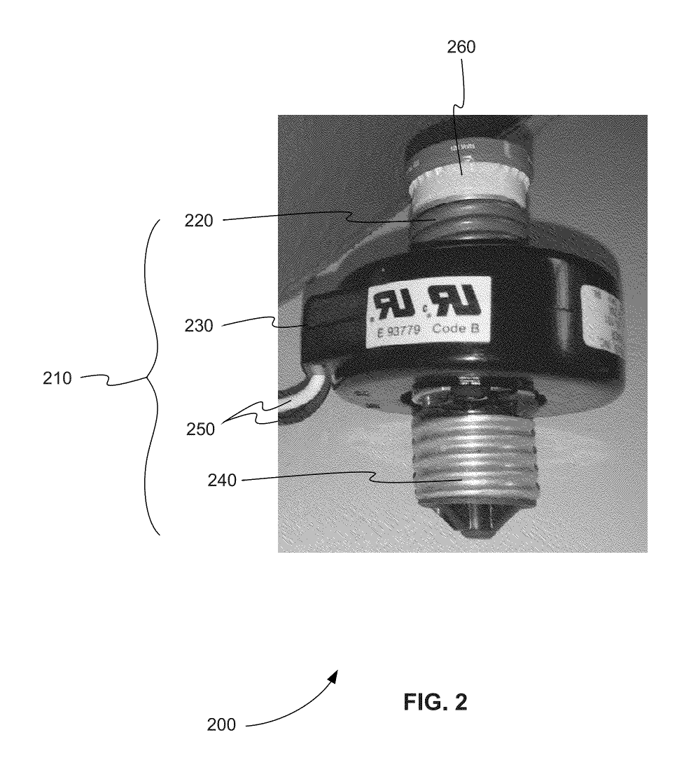

FIG. 2 is an exemplary alternate side view 200 of an Edison base fuse meter, in accordance with various embodiments. Edison base fuse meter 210 includes female Edison base connector 220 connected to socket extender 230, in turn, connected to male Edison base connector 240. In addition, wires 250 extend from socket extender 230. Female Edison base connector 220 is designed to receive Edison base fuse 260. Male Edison base connector 240 is designed to be threaded into a female Edison base connector of an Edison base fuse box (not shown).

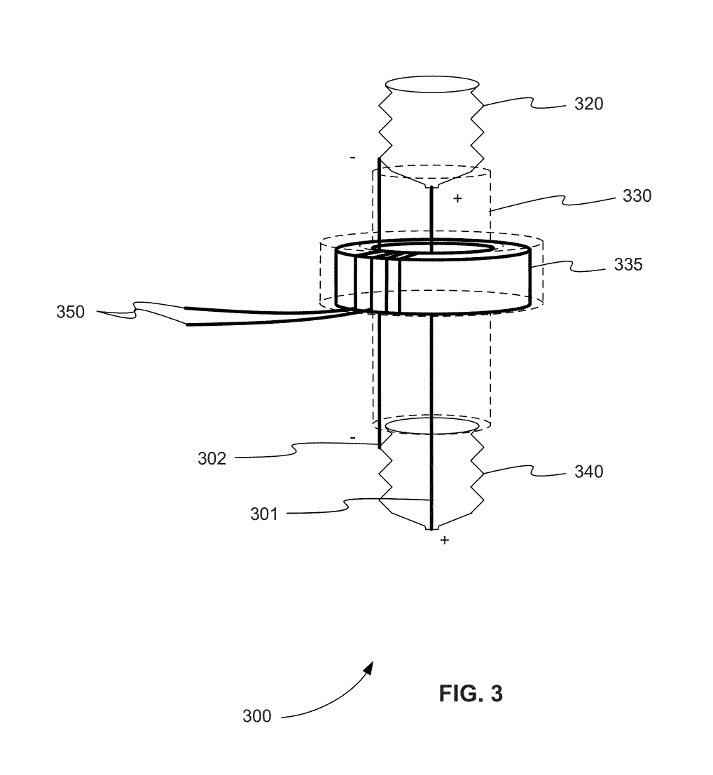

FIG. 3 is an exemplary schematic diagram of the electrical connections of an Edison base fuse meter 300, in accordance with various embodiments. Socket extender 330 (shown in dashed lines), for example, includes first wire 301 and second wire 302 of one or more cables. First wire 301 and second wire 302 electrically connect female Edison base connector 320 and male Edison base connector 340. Socket extender 330 also includes current measurement device 335 that surrounds first wire 301 and second wire 302. First wire 301 and second wire 302 are conductors of two or three conductor single phase cables, for example. Current measurement device 335 can be, but is not limited to, a current transformer (CT) or current clamp. Wires 350 are electrically connected to socket extender and are used for externally measuring the current induced in current measurement device 335.

As shown in FIG. 3, the Edison base fuse meter 300 only provides a part of the circuit needed to measure and display the power consumed. In various alternative embodiments, Edison base fuse meter 300 can include an entire circuit for measuring current and/or power, can include a means for displaying the power consumption, and can include a communications device for communicating the current and/or power to another device. The communications device can communicate over a wire or wirelessly, for example.

In early (e.g., pre/post World War 1) Edison fuse boxes, the fuse bases are physically restricted in smaller panels or in panels that have tightly spaced sockets. In various embodiments, the socket extender can be made with different shapes, for example, a right or oblique angle or can be made flexible, like a wire or extension cord, so that it can be used for these early Edison fuse boxes that are smaller or have tightly spaced sockets.

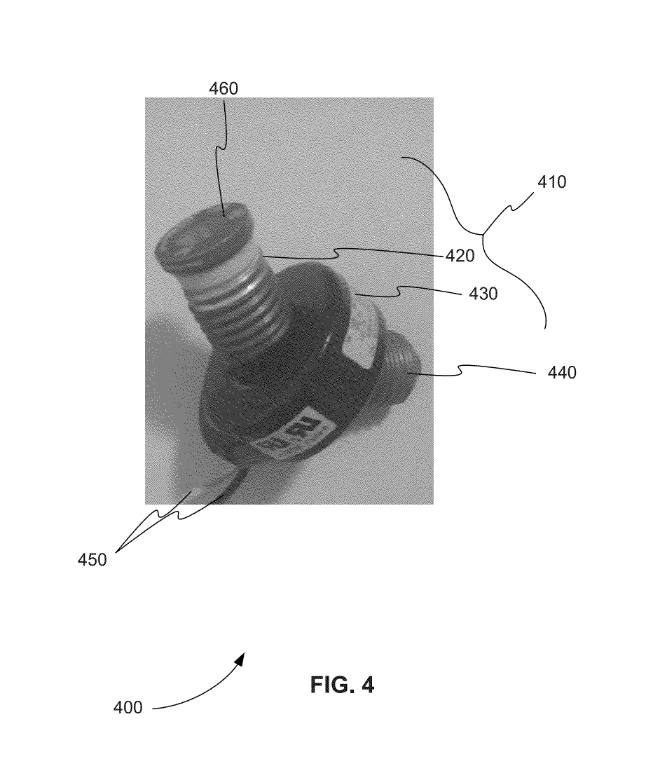

FIG. 4 is an exemplary side view 400 of an Edison base fuse meter with a socket extender that has an oblique angle, in accordance with various embodiments. Edison base fuse meter 410 includes female Edison base connector 420 connected to socket extender 430, in turn, connected to male Edison base connector 440. Socket extender 430 has an oblique angle so that it can be used for the early Edison fuse boxes that has smaller or tightly spaced sockets. In addition, wires 450 extend from socket extender 430. Female Edison base connector 420 is designed to receive Edison base fuse 460. In others words, Edison base fuse 460 is threaded into female Edison base connector 420. Male Edison base connector 440 is designed to be threaded into a female Edison base connector of an Edison base fuse box (not shown).

Similar to the configuration of FIG. 1, Edison base fuse meter 410 acts as a socket extender for an Edison base fuse box. Edison base fuse meter 410 provides a permanent solution for monitoring an electrical circuit, while requiring little or no modification to the Edison base fuse box. Depending on the length of Edison base fuse meter 410 the door of the Edison base fuse box may have to be modified. In various embodiments, for example, the door of the Edison base fuse box is extended to increase the workable space for Edison base fuse meter 410.

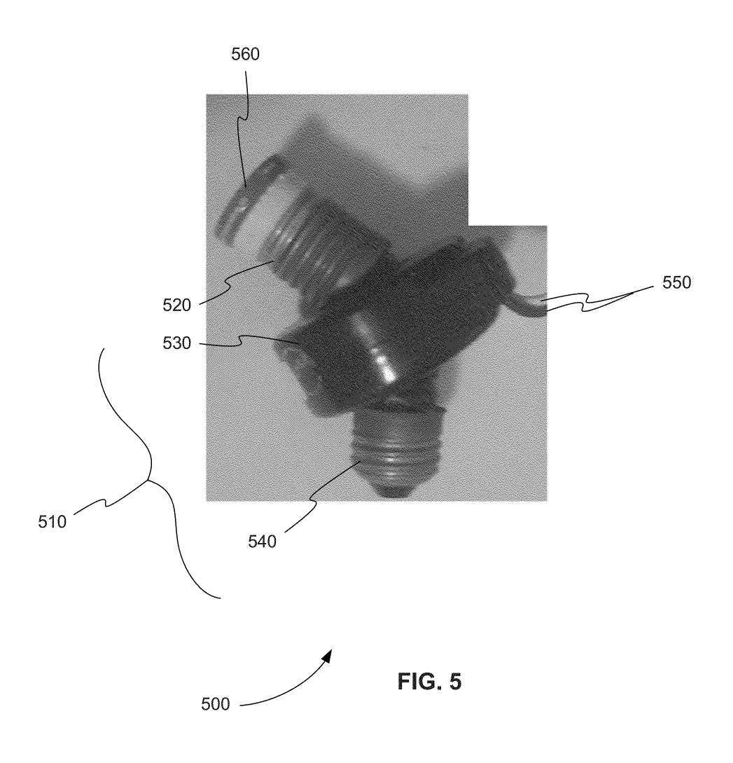

FIG. 5 is an exemplary alternate side view 500 of an Edison base fuse meter with a socket extender that has an oblique angle, in accordance with various embodiments. Edison base fuse meter 510 includes female Edison base connector 520 connected to socket extender 530, in turn, connected to male Edison base connector 540. Socket extender 530 has an oblique angle or right angle, so that it can be used for early Edison fuse boxes that are smaller or have tightly spaced sockets. In addition, wires 550 extend from socket extender 530. Female Edison base connector 520 is designed to receive Edison base fuse 560. Male Edison base connector 540 is designed to be threaded into a female Edison base connector of an Edison base fuse box (not shown).

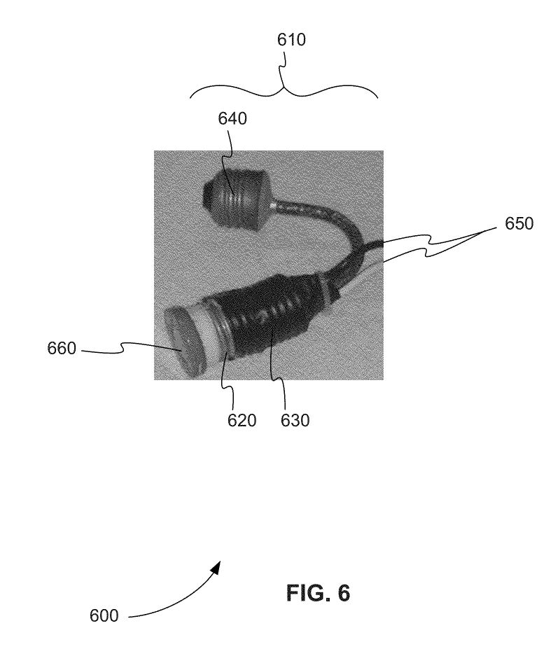

FIG. 6 is an exemplary side view 600 of an Edison base fuse meter with a flexible socket extender, in accordance with various embodiments. Edison base fuse meter 610 includes female Edison base connector 620 connected to socket extender 630, in turn, connected to male Edison base connector 640. Socket extender 630 is flexible, so that it can be used for early Edison fuse boxes that are smaller or have tightly spaced sockets. Socket extender 630, for example, includes a flexible cable that includes the conductors used to electrically connect Edison base connector 620 and Edison base connector 640. Socket extender also, for example, includes a current measurement device. In addition, wires 650 extend from socket extender 630. Female Edison base connector 620 is designed to receive Edison base fuse 660. In others words, Edison base fuse 660 is threaded into female Edison base connector 620. Male Edison base connector 640 is designed to be threaded into a female Edison base connector of an Edison base fuse box (not shown).

Similar to the configuration of FIG. 1, Edison base fuse meter 610 acts as a socket extender for an Edison base fuse box. Edison base fuse meter 610 provides a permanent solution for monitoring an electrical circuit, while requiring little or no modification to the Edison base fuse box. Depending on the length of Edison base fuse meter 610 the door of the Edison base fuse box may have to be modified. In various embodiments, for example, the door of the Edison base fuse box is extended to increase the workable space for Edison base fuse meter 610.

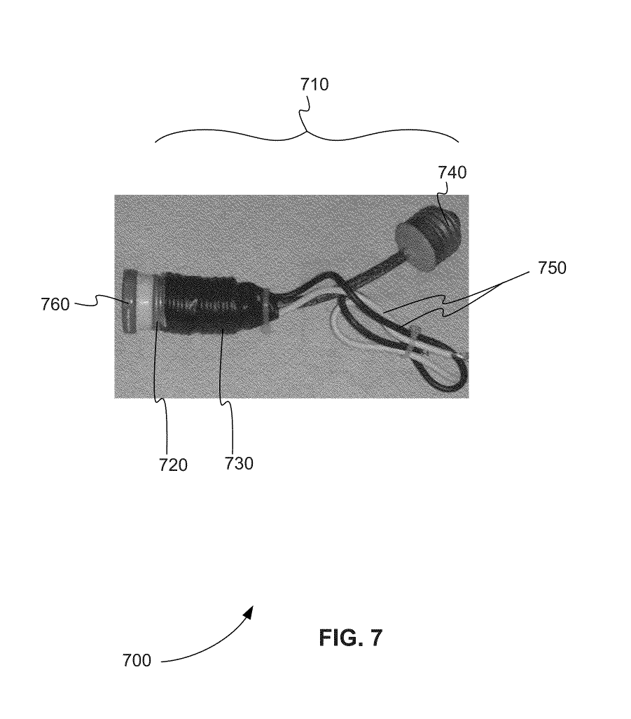

FIG. 7 is an exemplary alternate side view 700 of an Edison base fuse meter with a flexible socket extender, in accordance with various embodiments. Edison base fuse meter 710 includes female Edison base connector 720 connected to socket extender 730, in turn, connected to male Edison base connector 740. Socket extender 730 is flexible, so that it can be used for early Edison fuse boxes that are smaller or have tightly spaced sockets. In addition, wires 750 extend from socket extender 730. Female Edison base connector 720 is designed to receive Edison base fuse 760. Male Edison base connector 740 is designed to be threaded into a female Edison base connector of an Edison base fuse box (not shown).

Various embodiments are not limited to Edison base fuses or Edison base fuse boxes. One embodiment is a fuse meter for measuring the current or power through a cartridge fuse. This cartridge fuse meter includes a current measurement device and two current transformer wires. The current measurement device is made to surround a cartridge fuse as it is being held in a cartridge fuse box. The current measurement device is, for example, cylindrical housing with a hole in the center. The cartridge fuse is then slipped through the center of the cylindrical housing. Alternatively, the cylindrical housing is hinged so that it can be clamped around cartridge fuse.

Electrically, the current measurement device includes a current transformer or current clamp that also surrounds the cartridge fuse, so that a current is induced in the current transformer in response to the current in the cartridge fuse. The two current transformer wires are electrically connected to each end of the current transformer and are used for externally measuring the current induced in the current transformer.

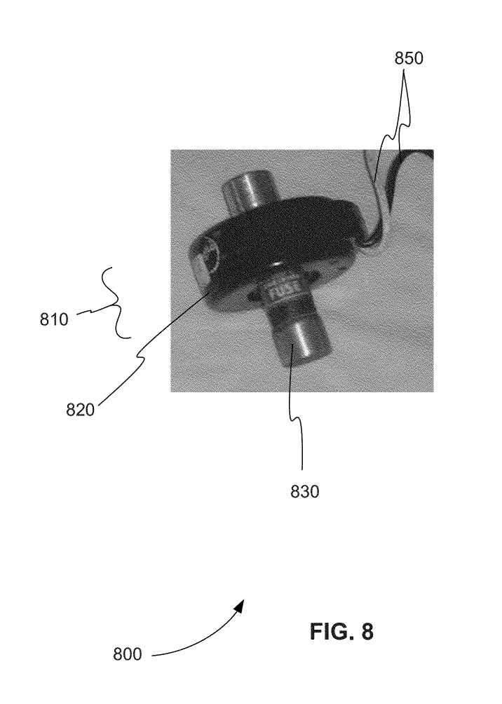

FIG. 8 is an exemplary side view 800 of a cartridge fuse meter surrounding a 60 amp cartridge fuse, in accordance with various embodiments. Cartridge fuse meter 810 is made to surround 60 amp cartridge fuse 830. Cartridge fuse meter 810 includes current measurement device 820 and wires 850 that extend from current measurement device 820. Current measurement device 820 houses a current transformer that also surrounds 60 amp cartridge fuse 830, and wires 850 are electrically connected to each end of the current transformer. As with the Edison fuse meter, depending on the size of cartridge fuse meter 810, the door of the cartridge fuse box or panel may have to be modified. In various embodiments, for example, the door of the cartridge fuse box is extended to increase the workable space for cartridge fuse meter 810.

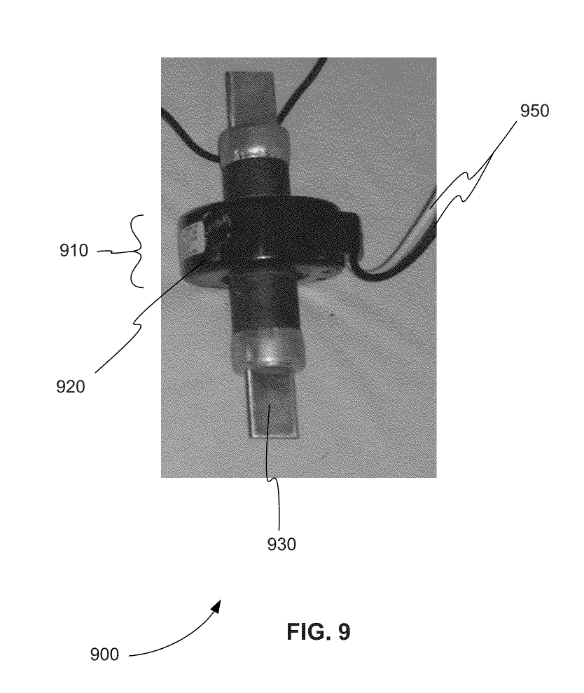

FIG. 9 is an exemplary side view 900 of a cartridge fuse meter surrounding a 100 amp cartridge fuse, in accordance with various embodiments. Cartridge fuse meter 910 is made to surround 100 amp cartridge fuse 930. Cartridge fuse meter 910 includes current measurement device 920 and wires 950 that extend from current measurement device 920. Current measurement device 920 houses a current transformer that also surrounds 100 amp cartridge fuse 930, and wires 950 are electrically connected to each end of the current transformer.

Another embodiment is a fuse meter for measuring the current or power through a circuit breaker. This circuit break meter includes a current measurement device and two current transformer wires. The current measurement device is made to surround a wire from a circuit breaker as it is being held in a circuit breaker panel or box. The current measurement device is, for example, cylindrical housing with a hole in the center. The wire from the circuit breaker is then slipped through the center of the cylindrical housing. Alternatively, the cylindrical housing is hinged so that it can be clamped around a wire from the circuit breaker. The current measurement device preferably surrounds the hot wire from the circuit breaker. However, the current measurement device can alternatively surround the common wire from the circuit breaker.

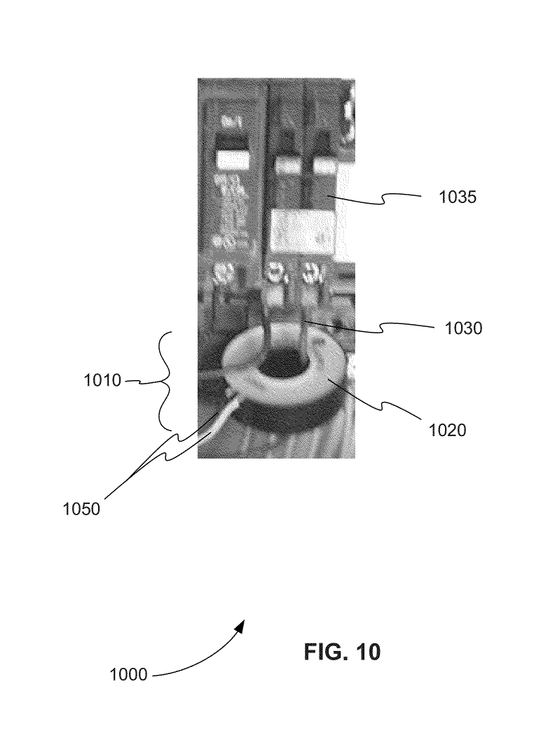

FIG. 10 is an exemplary view 1000 of a circuit breaker meter surrounding a wire of a circuit breaker, in accordance with various embodiments. Circuit breaker meter 1010 is made to wire 1030 from circuit breaker 1035. Circuit breaker meter 1010 includes current measurement device 1020 and wires 1050 that extend from current measurement device 1020. Current measurement device 1020 houses a current transformer that also surrounds wire 1030 from circuit breaker, and wires 1050 are electrically connected to each end of the current transformer. As with the Edison fuse meter, depending on the size of circuit breaker meter 1010, the door of the circuit breaker box or panel may have to be modified. In various embodiments, for example, the door of the circuit breaker box is extended to increase the workable space for circuit breaker meter 1010.

### Edison Base Fuse Meter

Returning to FIG. 3, in various embodiments, an Edison base fuse meter includes a female Edison base connector 320, a male Edison base connecter 340, a socket extender 330, and two current transformer wires 350. Socket extender 330 is physically connected in between female Edison base connector 320 and male Edison base connector 340. Socket extender 330 includes at least two wires 301 and 302 that electrically connect the terminals of female Edison base connector 320 and male Edison base connector 340. Socket extender 330 includes a current transformer 335 that surrounds one or more wires of the at least two wires 301 and 302 so that a transformer current is induced in the current transformer in response to a current in the one or more wires. Two current transformer wires 350 are electrically connected to each end of current transformer 335. Two current transformer wires 350 are used for externally measuring the transformer current induced in current transformer 335.

In various embodiments, socket extender 330 is flexible. In various embodiments, socket extender 330 include an oblique angle.

In various embodiments, the Edison base fuse meter further includes a circuit (not shown) electrically connected to two current transformer wires 350 to measure the transformer current induced in current transformer 335. The circuit, for example can be housed in socket extender 330.

In various embodiments, the circuit further converts the transformer current measurement to power and stores the calculated power in a memory not shown.

In various embodiments, the Edison base fuse meter further includes a display device that displays the calculated power stored in the memory. The display device can be, but is not limited to, a liquid crystal display (LCD) device or light emitting diode (LED) display device.

In various embodiments, the Edison base fuse meter further includes a communications device (not shown) that sends the calculated power stored in memory to a central processing device (not shown). A central processing device is used, for example, to monitor two or more Edison base fuse meters. The communications device can send the calculated power wirelessly or over a wire communications path.

In various embodiments, the communications device sends the measured transformer current to a central processing device. The communications device can send the measured transformer current wirelessly or over a wire communications path.

### Cartridge Fuse Meter

Returning to FIG. 8, in various embodiments, a cartridge fuse meter 810 includes, a housing 820 that surrounds and holds a center body portion of a cartridge fuse 830 and two current transformer wires 850. Housing 820 includes a current transformer that surrounds the center body portion of cartridge fuse 830 so that a transformer current is induced in the current transformer in response to a current in cartridge fuse 830. Housing 820 and cartridge fuse 830 are, for example, inserted together into a fuse box (not shown) as a single unit. Two current transformer wires 850 are electrically connected to each end of the current transformer. Two current transformer wires 850 are used for externally measuring the transformer current induced in the current transformer.

In various embodiments, housing 820 is attached to cartridge fuse 830 by sliding the cartridge fuse 830 through a center hole of housing 820. In various alternative embodiments, housing 820 includes a hinged clamping mechanism (not shown), like a current clamp, and housing 820 is attached to the cartridge fuse by clamping the hinged clamping mechanism around cartridge fuse 830.

In various embodiments, cartridge fuse meter 810 further includes a circuit (not shown) that electrically connects to two current transformer wires 850 to measure the transformer current induced in the current transformer.

In various embodiments, the circuit further converts the transformer current measurement to power and stores the calculated power in a memory (not shown).

In various embodiments, the Edison base fuse meter further includes a display device (not shown) that displays the calculated power stored in the memory. The display device can be, but is not limited to, a liquid crystal display (LCD) device or light emitting diode (LED) display device. The display device is attached to housing 820, for example.

In various embodiments, the Edison base fuse meter further includes a communications device (not shown) that sends the calculated power stored in memory to a central processing device (not shown). A central processing device is used, for example, to monitor two or more cartridge fuse meters. The communications device can send the calculated power wirelessly or over a wire communications path.

In various embodiments, the communications device sends the measured transformer current to a central processing device. The communications device can send the measured transformer current wirelessly or over a wire communications path.

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

What is claimed is:

1. An Edison base fuse meter, comprising:
a female Edison base connector;
a male Edison base connecter;
a socket extender physically connected in between the female Edison base connector and the male Edison base connector that includes at least two wires that electrically connect the terminals of the female Edison base connector and the male Edison base connector and that includes a current transformer that surrounds one or more wires of the at least two wires so that a transformer current is induced in the current transformer in response to a current in the one or more wires; and
two current transformer wires electrically connected to each end of the current transformer that are used for externally measuring the transformer current induced in the current transformer.

2. The Edison base fuse meter of claim 1, wherein the socket extender is flexible.

3. The Edison base fuse meter of claim 1, wherein the socket extender comprises an oblique angle.

4. The Edison base fuse meter of claim 1, further comprising a circuit electrically connected to the two current transformer wires to measure the transformer current induced in the current transformer.

5. The Edison base fuse meter of claim 4, wherein the circuit further converts the transformer current measurement to power and stores the calculated power in a memory.

6. The Edison base fuse meter of claim 5, further comprising a display device that displays the calculated power stored in the memory.

7. The Edison base fuse meter of claim 5, further comprising a communications device that sends the calculated power stored in memory to a central processing device.

8. The Edison base fuse meter of claim 7, wherein the communications device sends the calculated power wirelessly.

9. The Edison base fuse meter of claim 7, wherein the communications device sends the calculated power over a wire communications path.

10. The Edison base fuse meter of claim 4, further comprising a communications device that sends the measured transformer current to a central processing device

11. The Edison base fuse meter of claim 10, wherein the communications device sends the calculated power wirelessly.

12. The Edison base fuse meter of claim 10, wherein the communications device sends the calculated power over a wire communications path.

13. A cartridge fuse meter, comprising:
a housing that surrounds and holds a center body portion of a cartridge fuse and includes
a current transformer that surrounds the center body portion of the cartridge fuse so that a transformer current is induced in the current transformer in response to a current in the cartridge fuse, and
two current transformer wires electrically connected to each end of the current transformer that are used for externally measuring the transformer current induced in the current transformer.

14. The cartridge fuse meter of claim 13, wherein the housing is attached to the cartridge fuse by sliding the cartridge fuse through a center hole of the housing.

15. The cartridge fuse meter of claim 13, wherein the housing comprises a hinged clamping mechanism and the housing is attached to the cartridge fuse by clamping the hinged clamping mechanism around the cartridge fuse.

16. The cartridge fuse meter of claim 13, further comprising a circuit electrically connected to the two current transformer wires to measure the transformer current induced in the current transformer.

17. The cartridge fuse meter of claim 16, wherein the circuit further converts the transformer current measurement to power and stores the calculated power in a memory.

18. The cartridge fuse meter of claim 17, further comprising a display device that displays the calculated power stored in the memory.

19. The cartridge fuse meter of claim 17, further comprising a communications device that sends the calculated power stored in memory to a central processing device.

20. The cartridge fuse meter of claim 16, further comprising a communications device that sends the measured transformer current to a central processing device.
